(19) United States
(12) Patent Application Publication
(10) Pub. No.: US 2007/0233306 A1
(43) Pub. Date: Oct. 4, 2007

(54) Polishing apparatus and method of controlling the same

(75) Inventor: Yorio Takada, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 11/729,823

(22) Filed: Mar. 30, 2007

(30) Foreign Application Priority Data
Mar. 31, 2006 (JP) 2006-099684

(51) Int. Cl. H01L 21/304

(52) U.S. Cl. 700/121; 451/5; 700/282

(57) ABSTRACT

A polishing apparatus includes a slurry supply arm arranged on a polish pad for a polishing target and extending from a center of the polish pad into a radius direction; a plurality of nozzles attached to the slurry supply arm to supply the slurry from the plurality of nozzles; and a plurality of pumps, each of which supplies the slurry to one of the plurality of nozzles. A control unit controls each of the plurality of pumps independently.

### BACKGROUND OF THE INVENTION

1. Field of the Invention

The present invention relates to a polishing apparatus and a method of controlling the same.

2. Description of the Related Art

In a polishing apparatus used in a CMP (Chemical Mechanical Polishing) process, polishing is carried out while a polishing target is pushed against a polishing pad. At this time, slurry including abrasive material is supplied onto the polishing pad. The slurry is supplied from a nozzle attached to a slurry supply arm. Here, as a method of supplying the slurry, there are known (a) a single nozzle slurry supplying method in which a single nozzle is attached to the slurry supply arm, and (b) a multiple-nozzle slurry supplying method in which a plurality of nozzles are attached to the slurry supply arm.

In (a) the single nozzle slurry supplying method, a slurry of a flow amount preset in a polishing recipe is supplied from the center of the polishing pad. On the other hand, in (b) the multiple-nozzle slurry supplying method, slurry of a flow amount supplied from the plurality of nozzles is determined based on the polishing recipe. That is, the slurry of a total of the flow amounts individually preset for the respective nozzles is supplied from the plurality of nozzles. In any case, when the other polishing conditions are equal, the slurry of the flow amount preset in the polishing recipe is supplied from the respective nozzles.

It should be noted that when a polishing target is a semiconductor device in which miniaturization is advanced, global flatness and local flatness are strongly required in a CMP process. In the above-mentioned (a) single nozzle slurry supplying method and (b) multiple-nozzle slurry supplying method, the flatness of the polishing target greatly depends on a polishing pressure condition, and there is the limit on the improvement of in-plane uniformity. That is, a technique for improving the flatness irrespectively of the polishing pressure condition is desired.

In conjunction with the above description, Japanese Laid Open Patent Application (JP-P2001-113457A) discloses a chemical mechanical polishing method. In this conventional example, a thin film is made of an elastic material that is extended through the application of a fluid pressure between a polishing head for holding a wafer and the wafer, and while the fluid pressure is applied through the thin film to the wafer, the wafer is pushed against a polishing table, and the polishing is performed. When a distance by which the thin film is extended in a direction vertical to the main surface of the wafer is δ, the fluid pressure is applied to the thin film such that the distance δ meets the following equation

δ=(kpa4)/(Et3)

where k indicates a constant, p indicates the fluid pressure applied to the thin film, and a, E and t indicate a pulling tensile elastic coefficient, a thickness and a radius of the thin film, respectively.

### SUMMARY OF THE INVENTION

It is therefore an object of the present invention to provide a polishing apparatus that can improve a flatness of a polishing target, and a method of controlling the same.

Another object of the present invention is to provide a polishing apparatus that can improve a flatness of a polishing target irrespectively of a polishing pressure condition, and a method of controlling the same.

In an aspect of the present invention, a polishing apparatus includes a slurry supply arm arranged on a polish pad for a polishing target and extending from a center of the polish pad into a radius direction; a plurality of nozzles attached to the slurry supply arm to supply the slurry from the plurality of nozzles; and a plurality of pumps, each of which supplies the slurry to one of the plurality of nozzles. A control unit controls each of the plurality of pumps independently.

The polishing apparatus may further include a thickness measuring section connected with the control unit to measure thicknesses of the polishing target. The control unit may control the plurality of pumps based on the measured thicknesses.

In this case, the thickness measuring section measures the thicknesses of the polishing target before and after the polishing in a position corresponding to each of the plurality of nozzles. The control unit may calculate a polishing amount on the position corresponding to each of the plurality of nozzles from the thicknesses of the polishing target before and after the polishing, and control each of the plurality of pumps based on a corresponding one of the polishing amounts.

The control unit may divide each of the polishing amounts on the positions corresponding to the plurality of nozzles by an average of the polishing amounts. The control unit may control one of the plurality of pumps corresponding to the polishing amount such that a flow rate of the slurry is increased, when a division result is smaller than one, and control one of the plurality of pumps corresponding to the polishing amount such that a flow rate of the slurry is decreased, when the division result is larger than one.

Also, the control unit may perform the division by using a moving average value instead of the average of the polishing amounts when a plurality of the polishing targets are polished in order.

In another aspect of the present invention, a control method of a polishing apparatus, is achieved by providing a polishing apparatus having a plurality of nozzles configured to supply slurry from each of the plurality of nozzles, and a plurality of pumps configured to supply the slurries to the plurality of nozzles; and by controlling each of the plurality of pumps independently such that a polishing target is polished.

The control method may be achieved by further measuring initial thicknesses of the polishing target in positions corresponding to the plurality of nozzles; and measuring post-polishing thicknesses of the polishing target after polishing in positions corresponding to the plurality of nozzles. The controlling is achieved by controlling flow rates of the slurries supplied by the plurality of pumps based on the thicknesses of the polishing target before and after the polishing in the positions corresponding to the plurality of nozzles.

Also, the control method may be achieved by further measuring initial thicknesses of the polishing target in positions corresponding to the plurality of nozzles; and measuring post-polishing thicknesses of the polishing target after polishing in positions corresponding to the plurality of nozzles. The controlling may be achieved by calculating a polishing amount on each of the positions corresponding to the plurality of nozzles from the thicknesses of the polishing target before and after the polishing; and by determining flow rates of the slurries supplied by the plurality of pumps based on the polishing amounts.

In this case, the controlling may be achieved by dividing each of the polishing amounts on the positions corresponding to the plurality of nozzles by an average of the polishing amounts. The determining may be achieved by determining the flow rate of the slurry from one of the plurality of pumps corresponding to the polishing amount such that the flow rate of the slurry is increased, when a division result is smaller than one; and by determining the flow rate of the slurry from the one pump such that the flow rate of the slurry is decreased, when the division result is larger than one.

Also, the control method may be achieved by further polishing a plurality of the polishing targets in order under a same condition. The controlling may be performed each time each of the plurality of polishing targets is polished. A moving average value of the polishing targets which have been already polished may be used in the determining instead of the average of the polishing amounts.

### BRIEF DESCRIPTION OF THE DRAWINGS

FIG. 1 is a top view showing the configuration of a polishing apparatus of the present invention;

FIG. 2 is a front view showing the configuration of the polishing apparatus of the present invention;

FIGS. 3A to 3C are diagrams showing experimental results under different conditions that the slurry flow amount is independently controlled;

FIG. 4 is a diagram showing experiment results of relation between the polishing rates (nm/min) of the wafers polished under the slurry flow amounts in cases 1 to 3 of FIGS. 3A to 3C and a distances from the wafer center

FIG. 5 is a flowchart showing an operation of the polishing apparatus;

FIG. 6A is a diagram showing the calculation results;

FIG. 6B is a diagram showing calculation equations used in steps S30 to S70;

FIG. 7 is a graph showing a relation between a slurry flow amount and a division result (R/A ratio); and

FIG. 8 is a diagram showing a polishing recipe.

### DESCRIPTION OF THE PREFERRED EMBODIMENTS

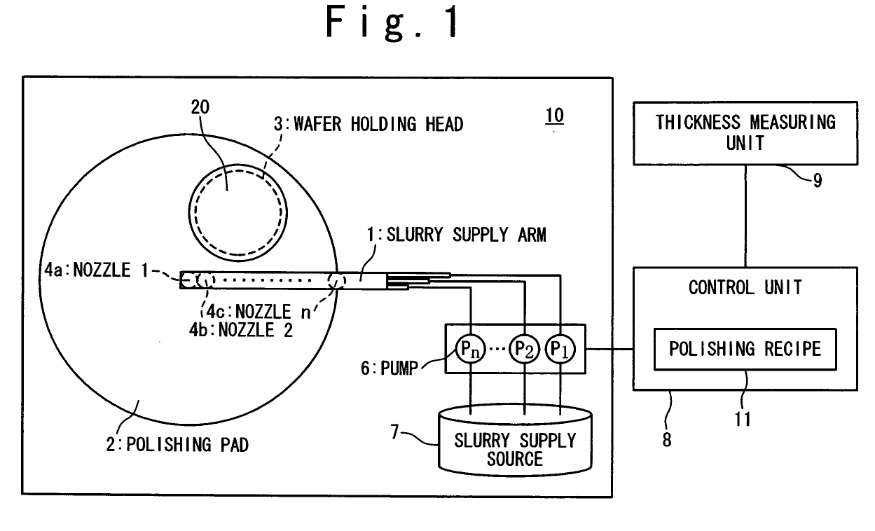

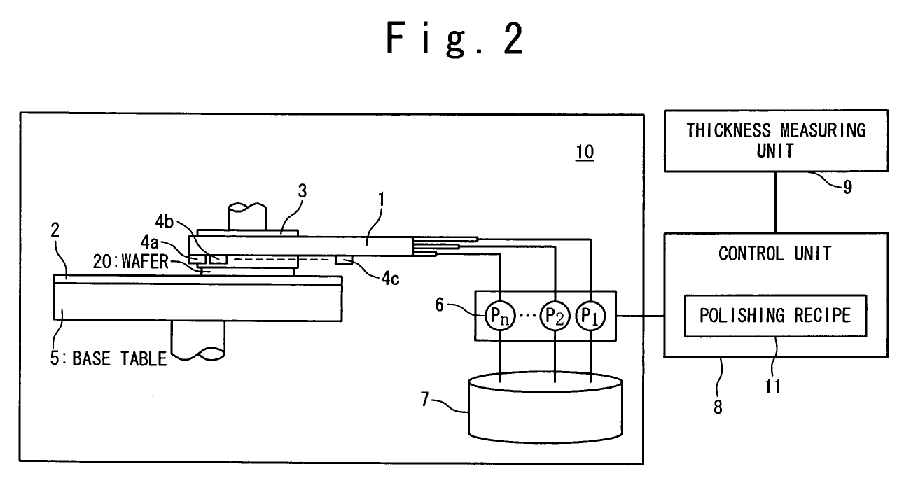

Hereinafter, a polishing apparatus according to the present invention will be described in detail with reference to the attached drawings. FIG. 1 is a top view showing the configuration of a polishing unit 10 according to this embodiment, and FIG. 2 is a front view showing the polishing unit 10 in this embodiment. The polishing apparatus for a CMP (Chemical Mechanical Polishing) operation whose polishing target is a semiconductor wafer 20 will be described as an example.

The polishing apparatus has a polishing unit 10, a control unit 8, and a thickness measuring unit 9. The polishing unit 10 has a slurry supply arm 1, a polishing pad 2, a wafer holding head 3, a plurality of nozzles 4 (4a, 4b to 4c), a base table 5, a plurality of pumps 6, and a slurry supply source 7. Also, the control unit 8 has a polishing recipe 11. The details of the respective components will be described below.

The base table 5 has the shape of a circular plate. The base table 5 is rotated in a predetermined rotation number when the semiconductor wafer 20 is polished. The polishing pad 2 is stuck and located on the upper surface of the base table 5. The wafer holding head 3 is located on a position opposite to the polishing pad 2. The wafer holding head 3 holds the wafer 20 and its polished surface is set on the side of the polishing pad 2. When the wafer 20 is polished, the wafer 20 is pushed against the polishing pad 2. Also, the wafer 20 itself is rotated when it is polished.

The slurry supply arm 1 is arranged in a predetermined distance from the polishing pad 2 above the polishing pad 2. The slurry supply arm 1 can be extended in a radius direction from the center of the polishing pad 2. The plurality of nozzles 4 (4a, 4b, 4c, . . . ) are attached to the slurry supply arm 1. Each nozzle is attached to face the side of the polishing pad 2 so that liquid slurry can be supplied to the side of the polishing pad 2. Each of the plurality of pumps 6 is connected to one of the plurality of nozzles 4, to supply the slurry to the nozzle 4 through a flow path (not shown) in the slurry supply arm 1. A flow amount of the slurry supplied by each of the plurality of pumps 6 can be controlled for every pump 6. In this way, the flow amount of the slurry supplied onto the polishing pad 2 by each nozzle 4 is independently controlled. The slurry supply source 7 is connected to the plurality of pumps 6. The plurality of pumps 6 are connected to the same slurry supply source 7. The slurry supply source 7 stores the liquid slurry. Since the pump 6 is driven, the liquid slurry is supplied to the nozzle 4 from the slurry supply source 7.

The thickness measuring unit 9 measures the thickness of the wafer before and after it is polished. The thickness measuring unit 9 is connected to the control unit 8. The data of the thickness measured by the thickness measuring unit 9 is reported or notified to the control unit 8. The control unit 8 controls the operation of the polishing unit 10 having the above configuration. As the control unit 8, a computer is exemplified. The control unit 8 has the polishing recipe 10. The various conditions when the wafer 20 is polished are defined in the polishing recipe 10. The control unit 8 controls the operation of the polishing unit 10 in accordance with the various conditions defined in the polishing recipe 10.

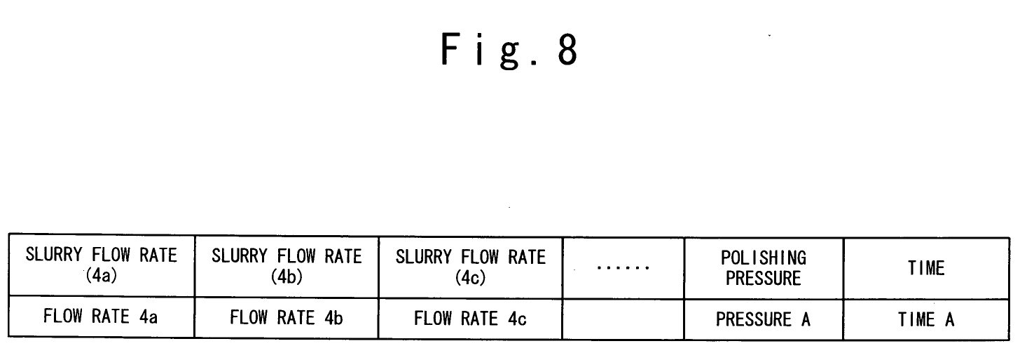

FIG. 8 is a diagram showing the polishing recipe 10. The conditions (a slurry flow amount, a polishing time, a polishing pressure and so on) when the wafer is polished are defined in the polishing recipe 10. Here, as for the slurry flow amount, the flow amounts from the plurality of nozzles (4a, 4b, 4c, - - - ) are defined.

Next, the method of operating the polishing apparatus having the above configuration will be described. It should be noted that the operation of the polishing apparatus to be described below is attained in accordance with a computer program installed in the control unit 8. Also, at the actual polishing process, the plurality of wafers are sequentially polished under the condition that the various conditions other than the slurry flow amounts are equal.

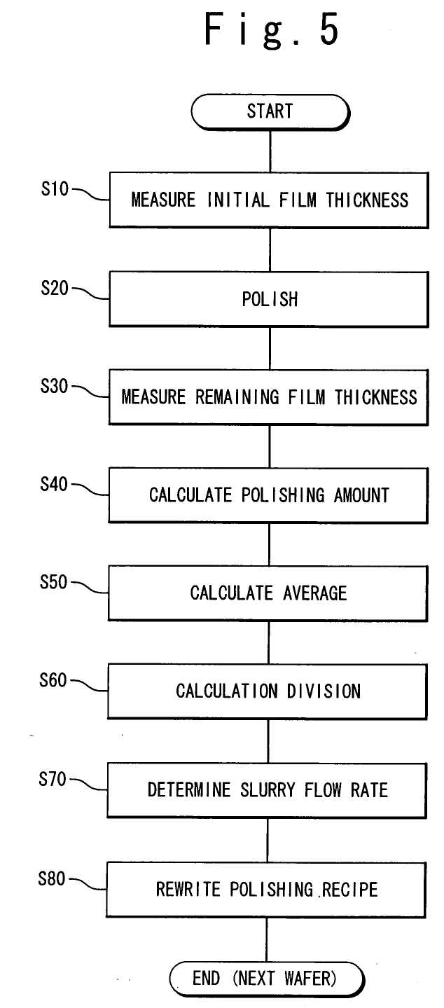

FIG. 5 is a flowchart showing an operation of the polishing apparatus. The operation at the steps S10 to S80 to be described below is the operation performed when a single wafer is polished.

### Step S1: Initial Film Thickness Measurement

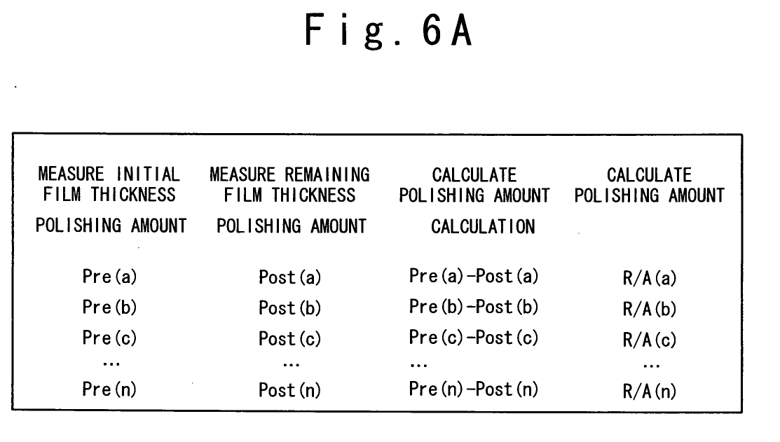

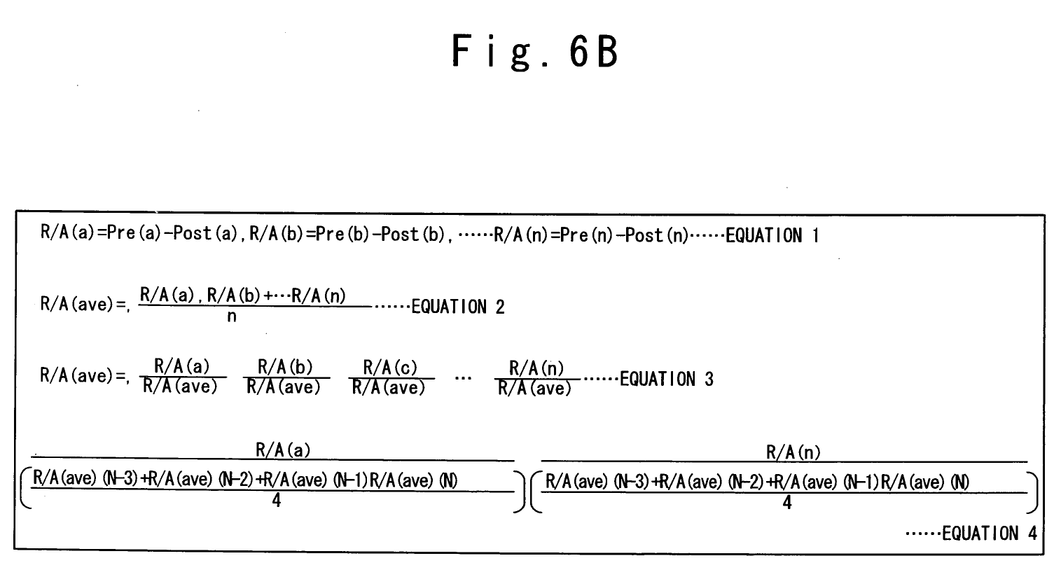

At first, the thickness measuring unit 9 is used to measure the thickness of the wafer 20 before it is polished. When the wafer is polished, the thicknesses in the portions corresponding to the positions where the slurries are supplied from the plurality of nozzles 4 are measured. That is, thicknesses Pre(a), Pre(b), Pre(c), . . . of the wafer 20 are measured for the positions of the plurality of nozzles 4a, 4b, 4c, . . . , as shown in FIG. 6A. The measured thickness data are reported to the control unit 8.

### Step S20: Polishing

Next, the wafer 20 as the polishing target is held by a wafer holding head 3 and polished. Here, the control unit 8 refers to the polishing recipe 11 and controls the flow amount of the slurry supplied by each of the plurality of pumps 6 so that the conditions defined in the polishing recipe 11 are satisfied. Also, the polishing pressure and the polishing time are controlled to satisfy the conditions defined in the polishing recipe 11.

The calculation equations used at the steps S30 to S70 are shown in FIG. 6B. The processes at the steps S30 to S50 will be described with reference to FIG. 6B.

### Step S30: Remaining Film Thickness Measurement

When the polishing has been completed, the polished surface of the wafer 20 is washed with water by using a water-washing apparatus (not shown). Moreover, the thickness measuring unit 9 is used to measure the thickness after the wafer 20 is polished. Similarly to the step S10, the thicknesses Post(a), Post(b), Post(c), . . . of the positions corresponding to the plurality of nozzles 4 are measured, as shown in FIG. 6A. The thickness measuring unit 9 reports the measured data to the control unit 8.

### Step S40: Calculation of Polishing Amount

Next, the control unit 8 calculates the polishing amounts R/A(a), R/A(b), R/A(c), . . . from the thickness data measured at the steps S10 and S30, as shown in FIG. 6A. The polished amount R/A(n) can be determined as [Pre(n)−Post(n)] (FIG. 6B, Equation 1).

### Step S50: Calculation of Average of Polishing Amounts

Moreover, the control unit 8 calculates an average R/A(ave) of the polishing amounts R/A(n) in the positions corresponding to the plurality of nozzles 4. Here, if the polished wafer 20 is the first wafer polished under the same condition or an initial wafer that the moving average to be described later cannot be used, the average is calculated as [R/A(ave)=(R/A(a)+R/A(b)+R/A(c)+ . . . )÷n] (n is the number of the measurement points (the number of the nozzles)) (FIG. 6B, Equation 2).

On the other hand, if at least one previous wafer is already polished under the same condition before the current wafer, the moving average is calculated. That is, if the current wafer polished at this time is the N-th wafer and the polishing amount average of the Na-th wafer is represented as [R/A(ave)(Na)], [Moving Average=(R/A(ave)(N−3)+R/A(ave)(N−2)+R/A (ave)(N−1)+R/A(ave)(N))÷4] is calculated.

It should be noted that when the moving average is calculated in the above equation, a case is described that the polishing amount averages of the four wafers polished until this time are used. The three wafers are a wafer prior to this time polished wafer, a wafer prior to this time polished wafer by one wafer, and a wafer prior to this time polished wafer by two wafers. However, the number of the wafers to be considered is suitably set.

### Step S60: Division

Next, the control unit 8 compares the polishing amount average R/A(ave) calculated at the step S50 and the polishing amounts R/A(a), R/A(b), R/A(c), . . . at the positions corresponding to the respective nozzles, respectively. That is, the divisions of R/A(a)÷R/A(ave), R/A(b)÷R/A(ave), R/A(c)÷R/A(ave), . . . are carried out for the positions corresponding to the respective nozzles, respectively (FIG. 6B, Equation 3). It should be noted that if the current wafer 20 polished at this time is the N-th wafer, the above moving average is used instead of R/A(ave) (FIG. 6B, Equation 4).

### Step S70: Determination of Slurry Flow Amount

Next, the flow amount of the slurry supplied from each nozzle is determined in accordance with the division result calculated at the step S60. If the division result at the step S60 is smaller than 1, the flow amount of the slurry supplied from the corresponding nozzle is determined to be increased. On the other hand, if it is greater than 1, the flow amount of the slurry supplied from the nozzle is determined to be decreased. Also, if it is equal, the slurry flow amount is not changed.

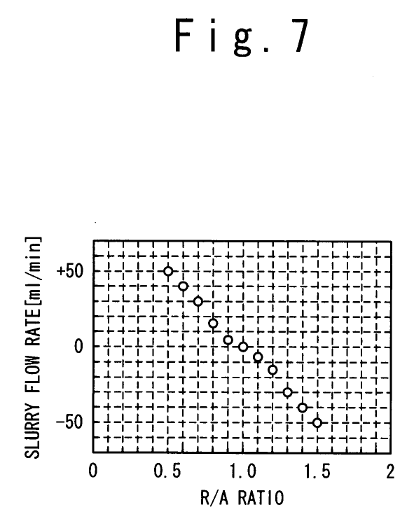

The operation of the step S70 can be determined based on a data table prepared in the control unit 8 and describing the relation between the predetermined slurry flow amount and the division result (R/A ratio), by the control unit 8 referring to the data table. FIG. 7 is a graph showing a relation between the slurry flow amount and the division result (R/A ratio). In FIG. 7, the relation is written in the data table so that the slurry flow amount is decreased when the R/A ratio is increased, and the slurry flow amount is increased when the R/A ratio is decreased.

### Step S80; Rewriting of Polishing Recipe

The slurry flow amount determined at the step S70 is rewritten in the polishing recipe 11 so as to update the polishing recipe 11. Consequently, the operation when one wafer is polished is completed.

The slurry flow amount supplied from each nozzle is independently determined through the process at the above steps S10 to S80. Each operation of the plurality of pumps 6 is controlled, such that the wafer to be polished after the completion of the process to the step S80 satisfies the conditions of the polishing recipe updated at the step S80. Thus, the slurry flow amount supplied from each nozzle is controlled.

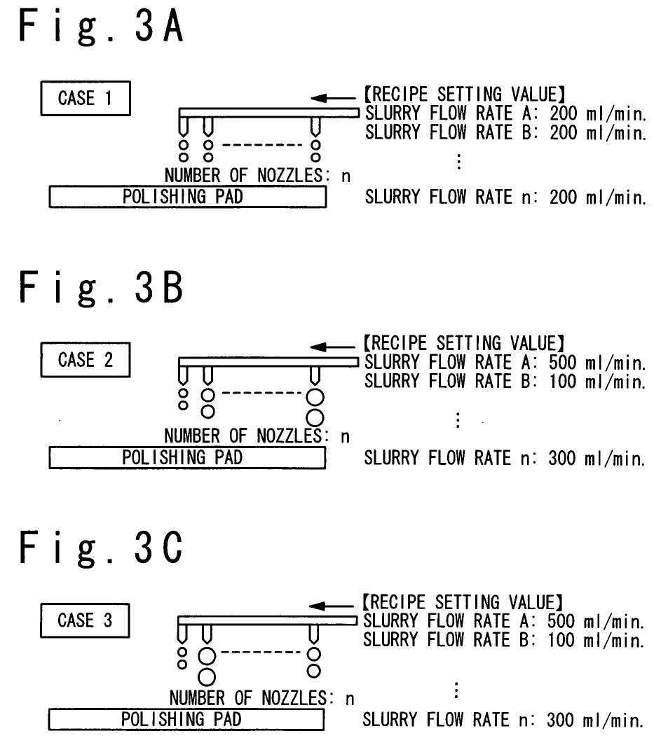

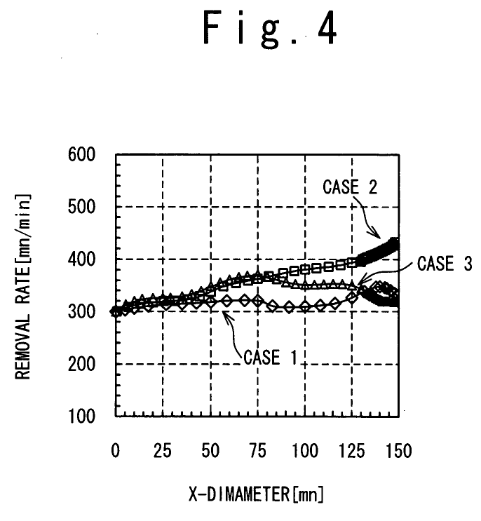

FIGS. 3A to 3C and 4 shows experiment results when a polishing rate of a polishing target can be controlled by independently controlling the flow amount of the slurry supplied from each nozzle. FIGS. 3A to 3C show the conditions (cases 1 to 3) of 3 kinds in the experiment. FIG. 4 is the experiment result showing the relation between the polishing rates (nm/min) of the wafers polished under the slurry flow amounts in the cases 1 to 3 of FIGS. 3A to 3C and the distances from the wafer center. The nozzle A is arranged closest to the center, the nozzle B is a nozzle on the side of the outer circumference, and the nozzle n is the nozzle arranged on the side of the outermost circumference. With reference to FIGS. 3A to 3C, in the case 1, the slurry flow amounts of the nozzles A to n are assumed to be 200 ml/min and constant. In the case 2, the slurry flow amounts of the nozzles A, B and n are assumed to be 50 ml/min, 100 ml/min and 300 ml/min, respectively. In the case 3, the slurry flow amounts of the nozzles A, B and n are assumed to be 50 ml/min, 300 ml/min and 300 ml/min, respectively. Also, in all of the cases 1 to 3, the slurry of a silica-based kind is used, and the polishing pad of IC1000 is used. It should be noted that the conditions other than the slurry flow amounts are same between the cases 1 and 3.

With reference to the result of FIG. 4, in the case 1, there is a portion where the polishing rates are partially different. However, the polishing rates are approximately 300 nm/min. The case 2 has a tendency that the polishing rate on the outer circumferential side becomes high. The case 3 has a tendency that the polishing rates of the center and the outer circumferential side are low and the polishing rate between them is high. In this way, it is known that the polishing rate at any position in the radius direction of the wafer can be controlled by changing the slurry flow amount.

As described above, according to this embodiment, the slurry flow amount supplied from each nozzle can be independently controlled. Thus, a profile of the polishing rates can be controlled even under the same condition (under the same polishing pressure condition).

Also, according to this embodiment, when the slurry flow amount is determined as described at S10 to S80 and the operation of the each pump is controlled. In this case, the polishing amount is increased in the wafer to be next polished at the position where the slurry flow amount is increased, and the polishing amount is decreased in the next wafer at the position where the slurry flow amount is decreased. Thus, it is made flat as a whole. In this way, since the slurry flow amount supplied from each nozzle can be independently determined, the polishing rate profile control can be performed even under the condition that the polishing pressure and the like are fixed. Therefore, the free degree of the condition setting is improved, thereby attaining the stabilization and diversification of the polishing rate profile control.

What is claimed is:

1. A polishing apparatus comprising:
a slurry supply arm arranged on a polish pad for a polishing target and extending from a center of said polish pad into a radius direction;
a plurality of nozzles attached to said slurry supply arm to supply said slurry from said plurality of nozzles;
a plurality of pumps, each of which supplies said slurry to one of said plurality of nozzles; and
a control unit configured to control each of said plurality of pumps independently.

2. The polishing apparatus according to claim 1, further comprising:
a thickness measuring section connected with said control unit to measure thicknesses of said polishing target,
wherein said control unit controls said plurality of pumps based on the measured thicknesses.

3. The polishing apparatus according to claim 2, wherein said thickness measuring section measures the thicknesses of said polishing target before and after said polishing in a position corresponding to each of said plurality of nozzles, and
said control unit calculates a polishing amount on the position corresponding to each of said plurality of nozzles from the thicknesses of said polishing target before and after the polishing, and controls each of said plurality of pumps based on a corresponding one of said polishing amounts.

4. The polishing apparatus according to claim 3, wherein said control unit divides each of said polishing amounts on the positions corresponding to said plurality of nozzles by an average of said polishing amounts, controls one of said plurality of pumps corresponding to said polishing amount such that a flow rate of said slurry is increased, when a division result is smaller than one, and controls one of said plurality of pumps corresponding to said polishing amount such that a flow rate of said slurry is decreased, when the division result is larger than one.

5. The polishing apparatus according to claim 4, wherein said control unit performs the division by using a moving average value instead of said average of said polishing amounts when a plurality of said polishing targets are polished in order.

6. A control method of a polishing apparatus, comprising:
providing a polishing apparatus having a plurality of nozzles configured to supply slurry from each of said plurality of nozzles, and a plurality of pumps configured to supply said slurries to said plurality of nozzles; and
controlling each of said plurality of pumps independently such that a polishing target is polished.

7. The control method according to claim 6, further comprising:
measuring initial thicknesses of said polishing target in positions corresponding to said plurality of nozzles; and
measuring post-polishing thicknesses of said polishing target after polishing in positions corresponding to said plurality of nozzles,
wherein said controlling comprises:
controlling flow rates of said slurries supplied by said plurality of pumps based on said thicknesses of said polishing target before and after said polishing in the positions corresponding to said plurality of nozzles.

8. The control method according to claim 6, further comprising:
measuring initial thicknesses of said polishing target in positions corresponding to said plurality of nozzles; and
measuring post-polishing thicknesses of said polishing target after polishing in positions corresponding to said plurality of nozzles,
wherein said controlling comprises:
calculating a polishing amount on each of the positions corresponding to said plurality of nozzles from the thicknesses of said polishing target before and after said polishing; and
determining flow rates of said slurries supplied by said plurality of pumps based on said polishing amounts.

9. The control method according to claim 8, wherein said controlling comprises:
dividing each of said polishing amounts on the positions corresponding to said plurality of nozzles by an average of said polishing amounts,
said determining comprises:
determining said flow rate of said slurry from one of said plurality of pumps corresponding to said polishing amount such that said flow rate of said slurry is increased, when a division result is smaller than one; and
determining said flow rate of said slurry from said one pump such that said flow rate of said slurry is decreased, when the division result is larger than one.

10. The control method according to claim 9, further comprising:
polishing a plurality of said polishing targets in order under a same condition,
wherein said controlling is performed each time each of said plurality of polishing targets is polished,
a moving average value of said polishing targets which have been already polished is used in said determining instead of said average of said polishing amounts.
